(19) United States
(12) Patent Application Publication
(10) Pub. No.: US 2006/0076314 A1
(43) Pub. Date: Apr. 13, 2006

(54) Method for forming a pattern

(75) Inventor: Naoaki Sakurai, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/236,578

(22) Filed: Sep. 28, 2005

(30) Foreign Application Priority Data
Sep. 28, 2004 (JP) 2004-282553

(51) Int. Cl. B44C 1/22; H01L 21/311

(52) U.S. Cl. 216/41; 438/694; 216/37

(57) ABSTRACT

One aspect of the present invention is directed to a method of forming a pattern. A first layer which comprises a polymerization initiator is selectively formed on a second layer of a substrate. A polymer layer is selectively formed on the first layer by subjecting an organic monomer to living radical polymerization using the polymerization initiator. The second layer is selectively etched using the polymer layer as a mask.

### CROSS REFERENCE TO RELATED APPLICATION

This application is based upon and claims the benefit of priority from prior Japanese Patent Application No. 2004-282553 filed on Sep. 28, 2004, the entire contents of which are incorporated herein by reference.

### BACKGROUND OF THE INVENTION

1. Field of the Invention

The present invention relates to a method for forming a pattern and a method of manufacturing an electronic device, in particular, a method for forming a pattern using living radical polymerization and a method for manufacturing an electronic device including a process of forming a pattern using living polymerization.

2. Description of the Related Art

Wiring of an electronic device such as a semiconductor device or a display apparatus is conventionally formed by forming a wiring material layer by sputtering or vacuum evaporation methods on a substrate, and then by forming a resist pattern on the wiring material layer. The resist pattern is formed by applying a resist on the substrate, patterning the resist and developing the resist to form the resist pattern. After the resist pattern is formed, the wiring material layer is selectively removed in order to form wiring using dry etching techniques such as RIE (Reactive Ion Etching), CDE (Chemical Dry Etching), or wet etching techniques using chemicals.

However, these conventional ways to form wiring involve complicated procedures using photolithography techniques to form a resist pattern. The complicated procedures need expensive patterning apparatus and developer, causing the procedures to be expensive.

Meanwhile, U.S. Pat. No. 6,919,158 discloses a method of forming wiring made from high polymer by taking advantage of a surface graft polymerization method or the like. However, this method can be cumbersome. Accordingly, the inventor of the present invention discloses herewith a process that achieves an effect of manufacturing an electronic wiring device by minimizing the need for expensive masking and or photolithography techniques.

### SUMMARY OF THE INVENTION

One aspect of the present invention relates to a method of forming a pattern. The method comprises selectively forming a first layer which comprises a polymerization initiator on a second layer of a substrate, selectively forming a polymer layer on the first layer by subjecting an organic monomer to living polymerization using the polymerization initiator; and selectively etching the second layer using the polymer layer as a mask.

The above aspect highlights certain aspects of the present invention. Additional objects, aspects and embodiments of the present invention are found in the following detailed description of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A to 1D show a schematic process to form a pattern on a SiOx film of a substrate.

FIGS. 2A to 2D shows a former part of a process to form wiring of an array substrate for a liquid crystal display.

FIGS. 3E to 3H show a latter part of the process to form the wiring of an array substrate for a liquid crystal display.

### DETAILED DESCRIPTION OF THE EMBODIMENTS

Unless specifically defined, all technical and scientific terms used herein have the same meaning as commonly understood by a skilled artisan in polymers and materials chemistry.

All methods and materials similar or equivalent to those described herein can be used in the practice or testing of the present invention, with suitable methods and materials being described herein. The U.S. patent mentioned herein is incorporated by reference in its entirety. In case of conflict, the present specification, including definitions, will control. Further, the materials, methods, and examples are illustrative only and are not intended to be limiting, unless otherwise specified.

### A First Embodiment

The first embodiment may be better appreciated upon consideration of the following. First, an underlying active layer comprising a polymerization initiator is selectively formed on a surface of a second layer of a substrate, wherein the second layer is capable of being etched by conventional means.

As the substrate, a silicon substrate or a glass substrate may be used.

As the second layer, a wiring material layer such as metal layer or an insulating material layer such as SiOx, SiN, TEOS (tetraethoxysilane) or porous organic material layers may be applied to the first layer. A transparent conductive material layer such as an ITO (Indium Tin Oxide) layer may be also used as the second layer. A polycrystalline silicon layer for an active layer of a MOS (Metal Oxide Semiconductor) transistor may also be applied as the second layer.

A selection of the polymerization initiator depends on the monomer to be polymerized and the polymerization conditions.

The monomers that can be used for the living polymerization are: ethylene, 1-propene, 1-butene, 1-pentene, 1-hexene, styrene and styrene derivatives, acrylamide, acrylic acid, methacrylic acid, acrylates, and methacrylates, such as methyl methacrylate. The preferred monomers are styrene and methyl methacrylate.

The living polymerization can be initiated by initiators that promote living radical, cationic, and anionic polymerization. Of these, initiators that promote living radical polymerization is preferred.

A silane coupling agent having an initiating group for polymerization can be generally used as the polymerization initiator. For example, in order to polymerize methyl methacrylate, 2-(4-chlorosulfonyphenyl) ethyltrichlorosilane (“CTS”) may be used.

The underlying active layer comprising the polymerization initiator can be formed using either one of two methods which will be explained next.

One of the methods is selectively applying a material for the underlying active layer on a surface of the second layer by an ink-jet method. The other one is coating a material for the underlying active layer on a whole surface of a second layer of the substrate, and then deactivating a polymerization activity of an unnecessary part of the coated material. Deactivating comprises exposing the unnecessary part using a mask with a light beam obtained from, for example, a UV lamp, or selectively irradiating the unnecessary part with a laser beam or an electron beam can be used.

The former method is convenient since the underlying active layer can be simply formed on selected portions of the second layer in a short period of time. However, other ways may be used to selectively form the underlying active layer.

Next, a polymer layer on the underlying active layer is formed by subjecting an organic monomer to living radical polymerization. The second layer is then etched selectively to form a pattern as desired using the polymer layer as a mask.

As noted above, methyl methacrylate (hereinafter referred to as MMA) or styrene may be used as monomers. These organic monomers are used in the form of organic solutions in which these organic monomers are dissolved in organic solvents. Suitable solvents include: benzene, toluene, o-xylene, m-xylene, p-xylene, a xylene mixture, anisole, chlorobenzene, o-dichlorobenzene, dichlorobenzene mixtures, or any combination of these solvents. Various additives may be added to the organic solutions.

The living radical polymerization is carried out by immersing the substrate into the organic monomer solution since the underlying active layer is maintained in contact with the organic solution containing the organic monomer.

It is preferred to minimize, more preferably exclude, oxygen from a reaction field of a polymerization while conducting living radical polymerization. Minimizing the oxygen level in the reaction field promotes a living radical polymerization, resulting in forming a thicker polymer layer. The thickness of the polymer layer can range from about 10 nm to about 450 nm, which includes about 50 mm, about 100 nm, about 150 nm, about 200 nm, about 250 nm, about 300 nm, about 350 nm, and about 400 nm. The preferred thickness of the polymer layer ranges from about 250 nm to about 350 nm. The more preferred thickness of the polymer layer is about 300 mm.

Reactive Ion Etching (“RIE”), Chemical Dry Etching (“CDE”), or a wet etching with a chemical material may be used to etch the etching layer.

As described above, a polymer layer which is used as a mask can be formed by selectively forming an underlying active layer comprising a polymerization initiator on an etching layer of a substrate, and then by subjecting an organic polymer to living radical polymerization using the polymerization initiator to form a polymer layer on the underlying active layer. Therefore, a process for forming a resist pattern becomes simpler and inexpensive relative to the conventional methods, which requires an expensive exposure apparatus and developer, involving processes of exposing and developing to form the resist pattern using photolithography techniques.

Living radical polymerization orderly polymerizes in a direction substantially orthogonal to the surface of the underlying active layer. The polymer layer accordingly has a shape closely following the underlying active layer. The polymer layer moreover has steep side faces. Therefore, a fine pattern closely following the pattern of the polymer layer can be formed by etching the second layer using the polymer layer obtained from living radical polymerization as a mask.

A fine pattern can be provided on a substrate without complicated procedures which are conventionally necessary for forming a resist pattern.

### A Second Embodiment

First, an underlying active layer containing a polymerization initiator is selectively formed on a surface of an etching layer of a substrate.

The same materials may be used for the substrate and the etching layer which will be etched.

A selection of the polymerization initiator depends on a kind of an organic polymer to be polymerized. A silane coupling agent having an initiating group for polymerization is generally used for the polymerization initiator.

An underlying active layer may be formed in substantially the same way shown in the first embodiment.

A first polymer layer that is capable of dissolving in a solvent is selectively formed on the underlying active layer by subjecting a first organic monomer to living radical polymerization. A second polymer layer having a reactive ion etching resistance (“RIE resistance”) is formed on the first polymer layer by subjecting a second organic monomer to living radical polymerization.

Styrene and MMA may be respectively applied as the first and second organic monomers, respectively. These organic monomers are used in the form of organic solutions in which these organic monomers are dissolved in organic solvents. The concentration of styrene and MMA is one in which living polymerization will occur. Various additives may be added to the organic solutions.

The living radical polymerization for forming the first polymer layer is carried out by immersing the substrate into the first organic monomer solution, since the underlying active layer is kept in contact with the first organic monomer solution.

The living radical polymerization for forming the second polymer layer is carried out by immersing the substrate on which the first polymer layer is formed into the second organic monomer, since the first polymer layer is kept in contact with the second organic monomer solution. Since the surface of the first polymer layer is still active due to the absence of oxygen, living radical polymerization occurs when the activated surface of the first polymer contacts the second organic monomer solution. As a result, the second polymer layer is formed as desired on the first polymer layer.

Reactive ion etching is then carried out to etch the second layer using the second polymer layer as a mask to form a pattern as desired.

As described above, the first polymer layer can be formed by selectively forming the underlying active layer comprising the polymerization initiator on the second layer of the substrate, then by subjecting the first organic polymer to living radical polymerization using the polymerization initiator to form the first polymer layer, and by subjecting the second organic monomer to living radical polymerization to form the second polymer layer. Therefore, a process for forming a resist pattern becomes simpler and inexpensive relative to the conventional way which needs an expensive exposure apparatus and developer, involving complicated exposing and developing processes to form a resist pattern using photolithography techniques.

Living radical polymerization orderly polymerizes in a direction substantially orthogonal to the surface of the underlying active layer. The first and second polymer layers accordingly have shapes closely following the underlying active layer. The polymer layers moreover have steep side faces. Therefore, a fine pattern closely following the pattern of the polymer layers can be formed by etching the etching layer using the second polymer layer as a mask.

Since the second polymer layer has an RIE resistance, the second polymer can avoid a rapid depletion when etching the etching layer using the second polymer as a mask. Meanwhile, the first and second polymer layers can be easily removed from the etched substrate since the first polymer layer having solubility in a solvent, and can be easily removed from the substrate and dissolved in the solvent. For example, xylene may be used as the solvent for removing the first and second polymer layers.

A fine pattern can be formed on a substrate without employing complicated procedures which are conventionally necessary for forming a resist pattern. In addition, the mask can be easily removed from the substrate after forming the pattern, which can make the process to form a resist pattern simpler and less expensive than a pattern produced by conventional means.

### A Third Embodiment

A method of manufacturing an electronic device shown in this third embodiment includes a process of etching a wiring material layer using substantially the same mask as one shown in the first embodiment. In other words, this method provides a process for selectively forming an underlying active layer comprising a polymerization initiator on a surface of the wiring material layer of a substrate, a process to form a polymer layer by submitting an organic monomer to a living radical polymerization on the underlying active layer, and a process to form a wiring by selectively etching the wiring material layer using the polymer layer as a mask.

Al, Al alloy such as Al—Cu or Al—Cu—Si, polycrystalline silicon, high melting point metal such as W, Mo, or Ti, silicide of these high melting point metals, or TiN may be used for the wiring material.

The wiring to be made can be used for a gate electrode, one or more wirings of the first or other layers, and so on.

As described above, the polymer layer for a mask in etching can be formed by selectively forming an underlying active layer comprising a polymerization initiator on an etching layer of a substrate, then by subjecting an organic polymer to living radical polymerization using the polymerization initiator to form the polymer layer. Therefore, a process for forming a resist pattern becomes simpler and inexpensive relative to the conventional way which needs an expensive exposure apparatus and developer, involving complicated processes of exposing and developing using photolithography techniques.

Since living radical polymerization orderly polymerizes in a direction substantially orthogonal to the surface of the underlying active layer, the polymer layer accordingly has a shape closely following the underlying active layer. The polymer layer moreover has steep side faces. Therefore, a fine pattern closely following the pattern of the polymer layer can be provided by etching the etching layer using the polymer layer as a mask.

As a result, an electronic device with fine wiring can be easily and inexpensively manufactured without exercising complicated processes to form a fine resist pattern.

### A Fourth Embodiment

A method of manufacturing an electronic device corresponding to a fourth embodiment includes a process of etching a wiring material layer using substantially the same mask shown in the second embodiment. In other words, this method includes selectively forming an underlying active layer which contains a polymerization initiator on a second layer of a substrate, selectively forming a first polymer layer on the underlying active layer by subjecting a first organic monomer to living radical polymerization using the polymerization initiator, selectively forming a second polymer layer on the first polymer layer by subjecting a first organic monomer to living radical polymerization, and selectively etching the second layer using the second polymer layer as a mask.

A material for the wiring layer may be the same or similar to the ones shown in the above embodiments. The wiring to be made can be used for a gate electrode, one or more wirings of the first or other layers, and so on.

The fourth embodiment makes it possible to omit an expensive exposure apparatus and developer which involve processes of exposing and developing to form a resist pattern using photolithography techniques, since a polymer layer to be used as a mask can be obtained by selectively forming an underlying active layer comprising a polymerization initiator on an etching layer of a substrate, then by subjecting a first organic polymer to living radical polymerization using the polymerization initiator to form a first polymer layer, and by subjecting a second organic polymer to living radical polymerization to form a second polymer layer.

Since living radical polymerization orderly polymerizes in a direction substantially orthogonal to the surface of the underlying active layer, the first and second polymer layers accordingly have shapes closely following the underlying active layer. The polymer layers moreover have steep side faces. Therefore, a fine pattern closely following the pattern of the polymer layers can be formed by etching the etching layer using the second polymer layer as a mask.

Since the second polymer layer has an RIE resistance, the second polymer can avoid a rapid depletion when etching the wiring material layer using the second polymer as a mask. Therefore a fine wiring can be obtained. Meanwhile, the first and second polymer layers can be easily removed from the substrate after the etching process since the first polymer layer having a solubility in a solvent can be easily removed off the substrate and solved to the certain solvent. As a result, a wiring having a high reliability relative to a conventional one can be obtained since the resist pattern is removed by oxygen ashing which may cause adverse effect on a wiring.

As a result, an electronic device with fine wiring can be easily and inexpensively manufactured without exercising complicated processes to form a fine resist pattern. In addition, since the mask can be simply removed from the substrate, the process to manufacture an electronic device becomes simpler.

Referring now to the drawings, wherein like reference numerals designate identical or corresponding parts throughout the several views, practical examples will be explained as follows.

### EXAMPLE 1

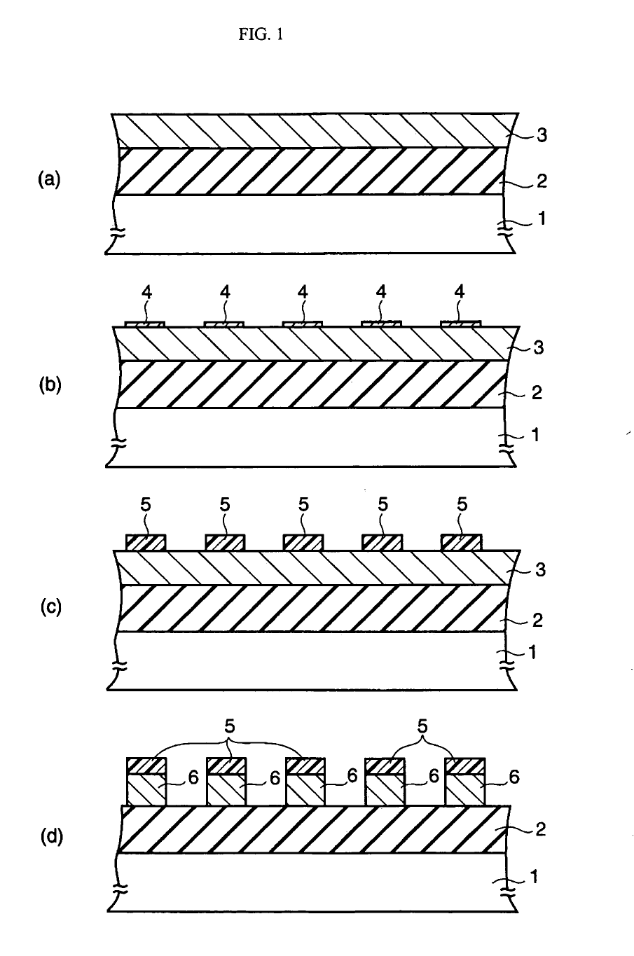

As shown in FIG. 1A, a SiOx film 2 is firstly deposited on a surface of a silicon substrate 1. An Al—Si alloy layer 3 is further evaporated onto SiOx film 2.

After Al—Si alloy layer 3 is cleaned with purified water and dried, a solution of CTS dissolved in toluene is applied to the surface of Al—Si alloy layer 3 in a line and space pattern with a 5-μm pitch by an ink-jet method. After the applied solution is dried, as shown in FIG. 1B, a zonal underlying active layer 4 forming a line and space pattern with a 5-μm pitch is formed on the surface of Al—Si alloy layer 3.

The silicon substrate is then immersed into a mixed solution comprising about 50 vol. % anisole, copper (I) bromide, sparteine, 2-bromo isobutyric acid ethyl ester, and MMA (mole ratio of copper (I) bromide:sparteine:2-bromo isobutyric acid ethyl ester:MMA is about 10:20:1:3000) at a reaction temperature that ranges from about 60° C. to about 80° C. It is also possible to provide vivration to the silicon substrate by a predetermined number per minute in order to prevent from making any gradations in the polymer.

The mixed solution is agitated for sixty minutes to subject MMA to living radical polymerization on underlying active layer 4 which is selectively formed on Al—Si alloy layer 3. As a result, as shown in FIG. 1C, a zonal polymer layer 5 of poly(methyl methacrylate) (hereinafter referred to as “PMMA”), is selectively formed. In this practical embodiment, the thickness of polymer layer is about 15 nm. Formation of polymer layer 5 on an Al—Si alloy layer 3 where no underlying active layer 4 is formed did not occur.

After the formation of polymer layer 5, the silicon substrate 1 is removed from the mixed solution, then cleaned with purified water and dried. Chemical dry etching with chlorinated etchant to selectively etch Al—Si alloy layer 3 is conducted using polymer layer 5 as a mask. As a result, as shown in FIG. 1D, an Al—Si alloy pattern 6 forming a line and space with a 5-μm pitch is provided, closely following the line and space pattern of polymer layer 5.

### EXAMPLE 2

Processes to form an underlying active layer and a polymer layer will be explained below. Other processes to form an Al—Si alloy pattern can be the same as those shown in other practical examples.

After a silicon substrate is cleaned with purified water and dried, a CTS solution is coated on a whole surface of an Al—Si alloy layer by a spin coat method. The spin coated CTS solution is dried to form an underlying active layer.

Ultra violet light emitted from a low-pressure mercury lamp whose electric power is 50 mW irradiates the underlying active layer through a Cr mask having a line and space pattern with a 5-μm pitch in order to deactivate a polymerization activity of an unnecessary portion of the underlying active layer. The silicon substrate is immersed into mixed solution comprising about 50 vol. % anisole, copper (I) bromide, sparteine, 2-bromo isobutyric acid ethyl ester, and MMA (mole ratio of copper (I) bromide:sparteine:2-bromo isobutyric acid ethyl ester:MMA is about 10:20:1:3000) at a reaction temperature that ranges from about 60° C. to about 80° C. It is also possible to provide vivration to the silicon substrate by a predetermined number per minute in order to prevent from making any gradations in the polymer.

While agitating the mixed solution for sixty minutes, living radical polymerization of the MMA is effected in the area where the polymerization activity of the underlying active layer was not deactivated. As a result, a polymer layer of PMMA with its thickness of about 15 nm is selectively formed in a line and space pattern with a 5-μm pitch.

In addition, an excimer ultraviolet lamp with 40 mW electric power can also deactivate a polymerization activity of the underlying active layer instead of the low-pressure mercury lamp. A plurality of polymer layers comprising PMMA with thicknesses of about 15 nm is selectively formed in a like manner in a line and space pattern with a 5-μm pitch.

### EXAMPLE 3

Processes to form an underlying active layer and a polymer layer will be explained below. Other processes to form an Al—Si alloy pattern can be the same as those shown in other practical examples.

An Al—Si alloy layer formed on a silicon substrate is firstly cleaned with purified water, then dried. A CTS solution is coated on a whole surface of an Al—Si alloy layer by a spin coat method, then dried to form an underlying active layer. An electron beam irradiates the underlying active layer in a line and space pattern with a 5-μm pitch to deactivate a polymerization activity of an unnecessary portion of the underlying active layer.

The silicon substrate is immersed into a mixed solution comprising comprising about 50 vol. % anisole, copper (I) bromide, sparteine, 2-bromo isobutyric acid ethyl ester, and MMA (mole ratio of copper (I) bromide:sparteine:2-bromo isobutyric acid ethyl ester:MMA is about 10:20:1:3000) at a reaction temperature that ranges from about 60° C. to about 80° C. It is also possible to provide vivration to the silicon substrate by a predetermined number per minute in order to prevent from making any gradations in the polymer.

While agitating the mixed solution for sixty minutes, living radical polymerization of the MMA is effected in the area where the polymerization activity of the underlying active layer was not deactivated. As a result, a polymer layer of PMMA with its thickness of about 15 nm is selectively formed in a line and space pattern with a 5-μm pitch.

In addition, a YAG laser beam, instead of an electron beam, may be used to irradiate the underlying active layer in a line and space pattern with a 5-μm pitch to deactivate a polymerization activity of an unnecessary portion of the underlying active layer.

In these three practical examples, the living radical polymerization may be conducted in an atmosphere with an oxygen concentration substantially less than the concentration of oxygen in air. There are many ways to achieve a reduced concentration of oxygen in the reaction field, and the following example is illustrative of this process. For example, a reaction vessel comprising the mixed solution and the silicon substrate can be enclosed by a lid covering an opening of the reaction vessel after the silicon substrate is immersed into the mixed solution. The reaction vessel is then deaerated using a hollow fiber module and a deaerating pump while agitating the mixed solution inside the reactive vessel. As a result, the thickness of the polymer layer dramatically increases from 15 nm to 25 nm. Alternatively, the reaction vessel may be flushed with a gas that does not inhibit living radical polymerization, such as, for example, nitrogen, argon, helium, carbon dioxide, or any combination thereof.

### EXAMPLE 4

After a polymer layer of PMMA with a thickness of about 15 nm is formed in a line and space pattern with a 5-μm pitch by the same or similar method shown in these three practical examples, the silicon substrate is immersed into a mixed solution comprising about 50 vol. % anisole, copper (I) bromide, sparteine, 2-bromo isobutyric acid ethyl ester, and styrene (mole ratio of copper (I) bromide:sparteine:2-bromo isobutyric acid ethyl ester:styrene) is about 10:20:1:3000) at a reaction temperature that ranges from about 90° C. to about 120° C. It is also possible to provide vivration to the silicon substrate by a predetermined number per minute in order to prevent from making any gradations in the polymer.

The mixed solution is then agitated for sixty minutes to further form a second polymer layer of polystyrene having a thickness of about 10 nm on top of the so-formed PMMA layer.

### EXAMPLE 5

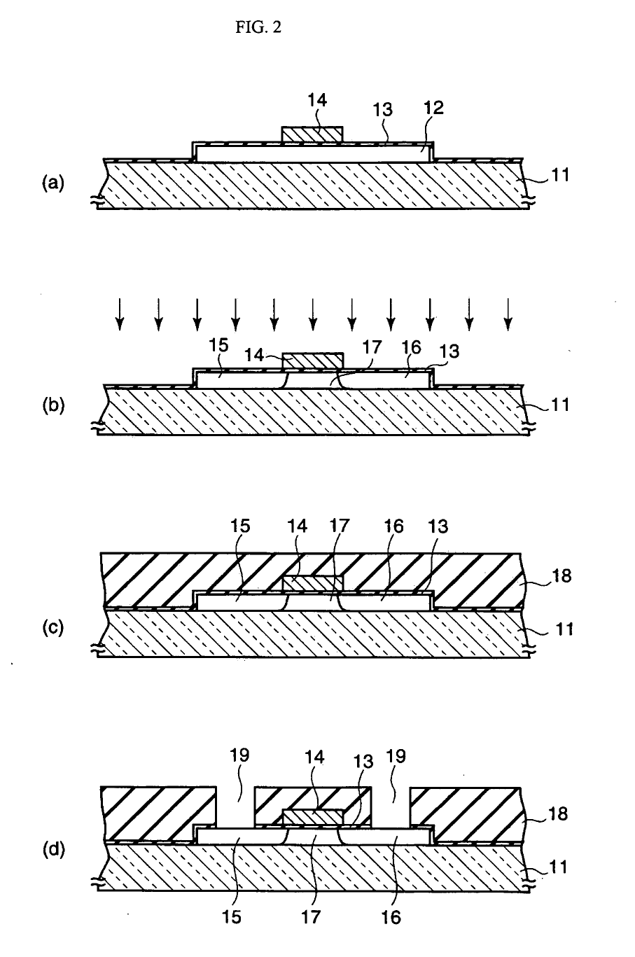

A glass substrate 11 (FIG. 2A) of 500 mm×600 mm in size coated with a SiO₂ film to prevent a surface contamination is provided as a substrate. An amorphous silicon (“a-Si”) film is deposited with a thickness of 50 nm on the surface of the glass substrate at the substrate temperature of 420° C. by a low pressure CVD method. Instead of the SiO₂ film, silicon nitride (“SiNx”) or a composition of SiNx and silicon oxide may be deposited to form a film.

A dopant, such as boron, may be introduced into the a-Si film for the purpose of threshold value control of a TFT (Thin Film Transistor). The a-Si-boron doped film was crystallized by an excimer laser annealing process. As a result, a boron-doped polycrystalline silicon film (“p-Si film”) is made. Alternatively, a boron-doped polycrystalline silicon film p-Si film may be obtained by lamp annealing.

A resist is coated on the p-Si film by a spin coat method. A resist pattern (not shown) is then formed by drying, patterning and developing the resist.

The p-Si film is selectively etched to form an island shaped p-Si film 12 with CF₄ and O₂ gases by a CDE (Chemical Dry Etching) method using the resist pattern as a mask. After the resist pattern is removed by an ashing process, a thin SiO₂ film 13 is deposited by a low pressure plasma CVD method for forming a gate insulating film using TEOS as a material gas. The SiO₂ film 13 is deposited on glass substrate 11 and p-Si film 12 as shown in FIG. 2A with a thickness of 20 nm. Aluminum is subsequently deposited on SiO₂ film 13 by a vapor deposition method. The aluminum is then selectively etched using a resist pattern (not shown) as a mask to form a gate electrode 14.

Referring to FIG. 2B, An impurity such as phosphorous is selectively doped to an island-shaped p-Si film 12 using gate electrode 14 as a mask. As a result, an n⁺-type source region 15 and drain region 16, and a p-type channel region 17 are formed in a p-Si film 12.

As shown in FIG. 2C, a silicon nitride (SiNx) film 18 is deposited on a whole area for forming an interlayer insulation film by a low pressure CVD method. A resist pattern (not shown) is then formed as a mask on SiNx film 18. SiNx film 18 and SiO₂ film 13 are selectively etched by a wet etching method using the resist pattern as a mask. As a result, as shown in FIG. 2D, contact holes 19 whose bottoms respectively reach source region 15 and drain region 16, are opened.

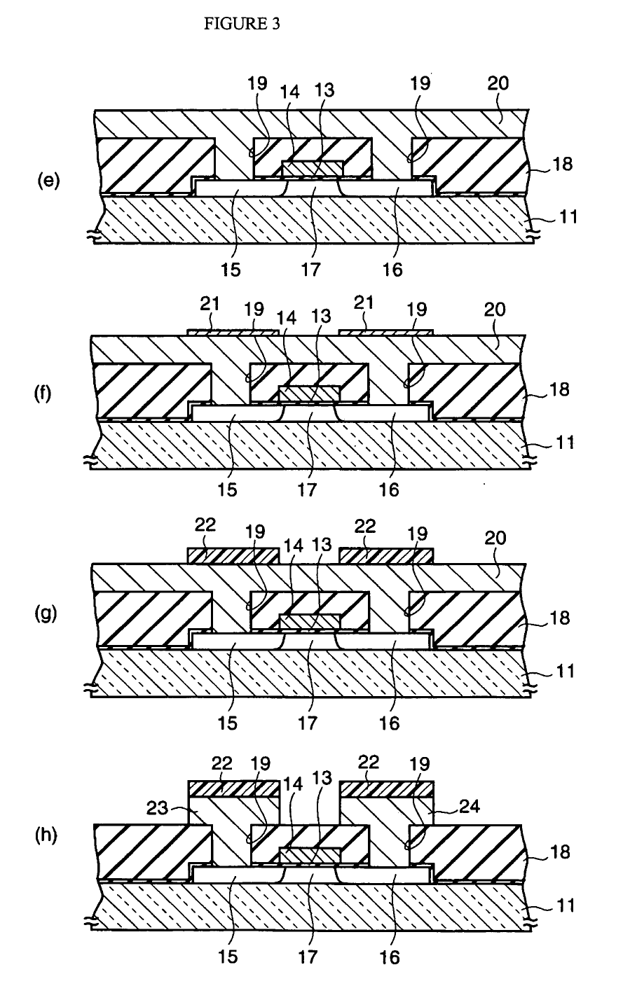

As shown in FIG. 3E, an Al—Si—Cu alloy layer 20 as a wiring material layer is deposited by a sputtering method onto SiNx film 18 and contact holes 19.

Al—Si—Cu alloy layer 20 is cleaned with purified water, then dried. A CTS solution the same or similar to one shown in the first practical example, is applied to a part of Al—Si—Cu alloy layer 20 where a wiring can be made by an ink-jet method. After the applied CTS solution is dried, as shown in FIG. 3F, an underlying active layer 21 is selectively formed on the surface of Al—Si—Cu alloy layer 20.

Glass substrate 11 is then immersed into a mixed solution comprising about 50 vol. % anisole, copper (I) bromide, sparteine, 2-bromo isobutyric acid ethyl ester, and MMA (mole ratio of copper (I) bromide:sparteine:2-bromo isobutyric acid ethyl ester:MMA is about 10:20:1:3000) at a reaction temperature that ranges from about 60° C. to about 80° C. It is also possible to provide vivration to the silicon substrate by a predetermined number per minute in order to prevent from making any gradations in the polymer.

While agitating the mixed solution for sixty minutes, MMA in the mixed solution is subjected to living radical polymerization on underlying active layer 21 which is selectively formed. As a result, as shown in FIG. 3G, a polymer layer 22 of PMMA having a thickness of about 15 nm is selectively formed on the surface of Al—Si—Cu alloy layer 20. No formation of polymer layer 22 on Al—Si—Cu alloy layer 20 where no underlying active layer 21 is formed is observed.

After the living radical polymerization, glass substrate 11 is pulled out from the mixed solution, then washed with purified water and dried. Al—Si—Cu alloy layer 20 is selectively etched by a CDE method with chlorinated etchant using polymer layer 22 as a mask. As a result, a source wiring 23 and a drain wiring 24 which respectively connects to source region 15 and drain region 16 via contact holes 19, are finally formed. These wirings 23 and 24 have shapes closely following the pattern of polymer layer 22.

Polymer layer 22 is then removed with an organic solvent. An array substrate having TFTs and a liquid crystal display therewith is subsequently manufactured by ordinary methods.

Obviously, numerous modifications and variations of the present invention are possible in light of the above teachings. It is therefore to be understood that within the scope of the appended claims, the invention may be practiced otherwise than as specifically described herein.

1. A method of forming a pattern, comprising:
selectively forming a first layer which comprises a polymerization initiator on a second layer of a substrate;
selectively forming a polymer layer on the first layer by subjecting an organic monomer to living radical polymerization using the polymerization initiator; and
selectively etching the second layer using the polymer layer as a mask.

2. The method of forming a pattern according to claim 1, wherein selectively forming a first layer on the second layer of the substrate comprises
selectively forming an underlying active layer on the second layer of the substrate.

3. The method of forming a pattern according to claim 2, wherein selectively forming the underlying active layer comprises
selectively applying a material which comprises the polymerization initiator on the second layer by an ink-jet method to selectively form the underlying active layer.

4. The method of forming a pattern according to claim 2, wherein selectively forming the underlying active layer comprises
coating the second layer of the substrate with a material which comprises the polymerization initiator; and
selectively deactivating a polymerization activity of the material to selectively form the underlying active layer.

5. A method of forming a pattern, comprising:
selectively forming a first layer which comprises a polymerization initiator on a second layer of a substrate;
selectively forming a first polymer layer on the first layer by subjecting a first organic monomer to living radical polymerization;
selectively forming a second polymer layer on the first polymer by subjecting a second organic monomer to living radical polymerization; and
selectively etching the second layer using the second polymer layer as a mask.

6. The method of forming a pattern according to claim 5, wherein selectively forming the first layer on the second layer comprises
forming an underlying active layer on a part or whole of the surface of the second layer.

7. The method of forming a pattern according to claim 6, wherein the first polymer layer is capable of being dissolved in a solvent.

8. The method of forming a pattern according to claim 7, wherein selectively forming the underlying active layer comprises
selectively applying a material which comprises the polymerization initiator on the second layer by an ink-jet method to selectively form the underlying active layer.

9. The method of forming a pattern according to claim 7, wherein selectively forming the underlying active layer comprises
coating the whole surface of the second layer with a material which comprises the polymerization initiator; and
selectively deactivating a polymerization activity of the material to selectively form the underlying active layer.

10. The method of forming a pattern according to claim 9, wherein selectively deactivating the polymerization activity of the material comprises
masking and irradiating the material.

11. The method of forming a pattern according to claim 9, wherein selectively deactivating the polymerization activity of the material comprises
selectively irradiating the material with a laser beam, an electron beam, or a UV lamp.

12. The method of forming a pattern according to claim 6, wherein the second polymer layer has a reactive ion etching resistance, and
selectively etching the second layer comprises
etching the second layer by reactive ion etching.

13. The method of forming a pattern according to claim 12, wherein selectively forming an underlying active layer comprises
selectively applying a material which comprises the polymerization initiator on the second layer by an ink-jet method to selectively form the underlying active layer.

14. The method of forming a pattern according to claim 12, wherein selectively forming an underlying active layer comprises
coating the second layer with a material which comprises the polymerization initiator; and
selectively deactivating a polymerization activity of the material to selectively form the underlying active layer.

15. The method of forming a pattern according to claim 14, wherein selectively deactivating a polymerization activity of the material comprises
masking and irradiating the material.

16. The method of forming a pattern according to claim 14, wherein selectively deactivating the polymerization activity of the material comprises
selectively irradiating the material with a laser beam, an electron beam, or with a UV lamp.

17. A method of manufacturing an electronic device, comprising:
selectively forming an underlying active layer which comprises a polymerization initiator on a wiring material layer of a substrate;
selectively forming a polymer layer on the underlying active layer by subjecting an organic monomer to living radical polymerization using the polymerization initiator; and
selectively etching the wiring material layer using the polymer layer as a mask to form a wiring for the electronic device.

18. The method of manufacturing an electronic device according to claim 17, which further comprises
removing the polymer layer from the wiring material layer by immersing the wiring material layer comprising the polymer layer in a solvent.
